(19) United States
(12) Patent Application Publication
(10) Pub. No.: US 2025/0048710 A1
(43) Pub. Date: Feb. 6, 2025

(54) SELF-ALIGNED BACKSIDE VIA WITH BURIED SEMICONDUCTOR STRUCTURE AND TRENCH ISOLATION ETCHBACK

(71) Applicant: Taiwan Semiconductor Manufacturing Co., Ltd., Hsinchu (TW)

(72) Inventors: Lo-Heng CHANG, Hsinchu (TW); Huan-Chieh SU, Hsinchu (TW); Chun-Yuan CHEN, Hsinchu (TW); Kuo-Cheng CHIANG, Hsinchu (TW); Chih-Hao WANG, Hsinchu (TW)

(21) Appl. No.: 18/411,675

(22) Filed: Jan. 12, 2024

Related U.S. Application Data
(60) Provisional application No. 63/517,589, filed on Aug. 3, 2023.

(51) Int. Cl. H01L 29/417; H01L 21/762; H01L 29/06; H01L 29/40; H01L 29/423; H01L 29/66; H01L 29/775; H01L 29/786

(52) U.S. Cl. CPC H01L 29/4175; H01L 21/76224; H01L 29/0673; H01L 29/401; H01L 29/42392; H01L 29/66439; H01L 29/66553; H01L 29/775; H01L 29/78696

(57) ABSTRACT

An integrated circuit includes a substrate having a semiconductor layer. The integrated circuit includes a transistor. The transistor includes stacked channels above the semiconductor layer, a first source/drain region in contact with the channels, and a second source/drain region in contact with the channels. A backside source/drain contact is positioned in the substrate directly below and electrically coupled to the first source/drain region. A frontside source/drain contact is directly above and electrically coupled to the first source/drain region. A bottom semiconductor structure is positioned below the second source/drain region and in contact with the semiconductor layer.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1U are perspective, side-sectional, and plane views of an integrated circuit at intermediate stages of processing, in accordance with some embodiments.

FIGS. 2A-2B are cross-sectional views of an integrated circuit, in accordance with some embodiments.

FIGS. 3A-3C are cross-sectional views of an integrated circuit, in accordance with some embodiments.

FIG. 4 is a flow diagram of a method for forming an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets). Gate-drain capacitance (“Cgd”) is increased due to larger metal gate endcap and increased source/drain epitaxy size.

Embodiments of the disclosure provide transistors having a plurality of stacked channels above a semiconductor layer of a substrate. Embodiments of the present disclosure form source/drain trenches extending into the semiconductor layer of the substrate. Embodiments of the present disclosure form bottom semiconductor structures in the portions of the source/drain trenches that extend into the semiconductor layer of the substrate. The bottom semiconductor structures are selectively etchable with respect to the semiconductor layer. Bottom isolation structures are formed on the bottom semiconductor structures in the source/drain trenches. The source/drain regions are then formed in the source/drain trenches on the bottom isolation structures such that the bottom isolation structures separate the source/drain regions from the bottom semiconductor structures. Backside source/drain contacts can be formed in contact with selected source/drain regions by selectively removing the bottom semiconductor structure and bottom isolation region at the selected source/drain regions. The result is that backside source/drain contacts can be formed with very small pitches and small critical dimensions (CD). This reduces leakage currents between the backside source/drain contacts and the gate metals of the transistors. Better functioning integrated circuits are produced and wafer yields are increased.

The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

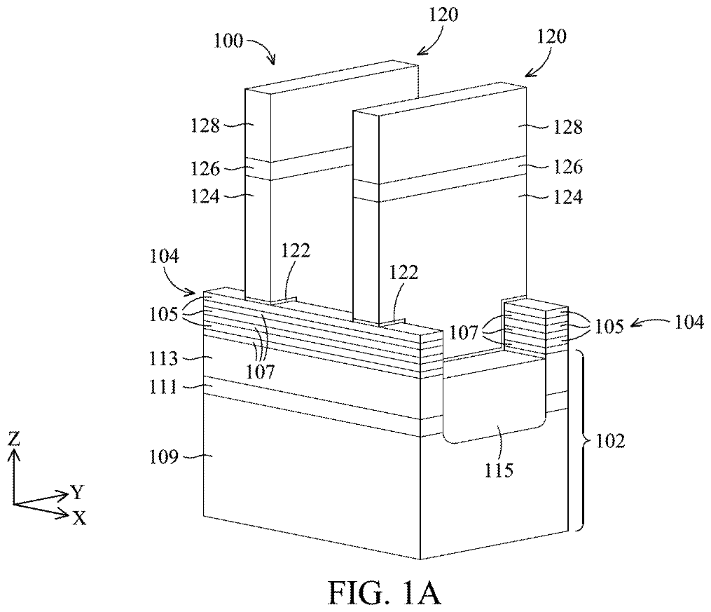

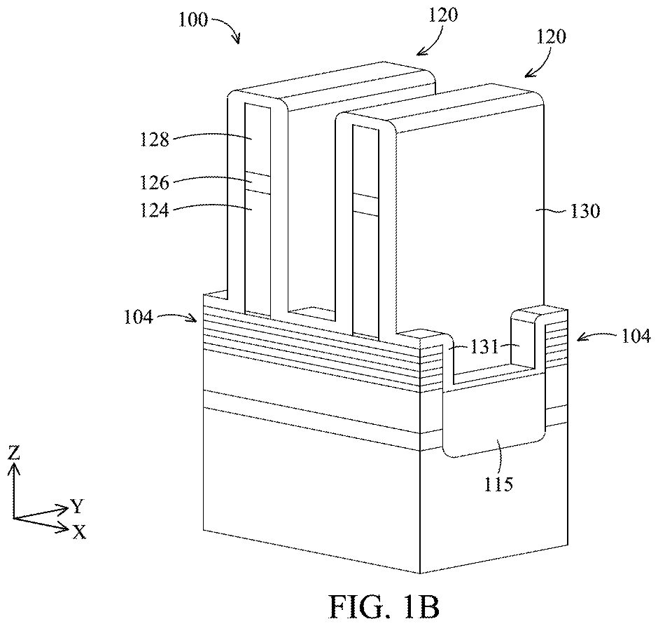

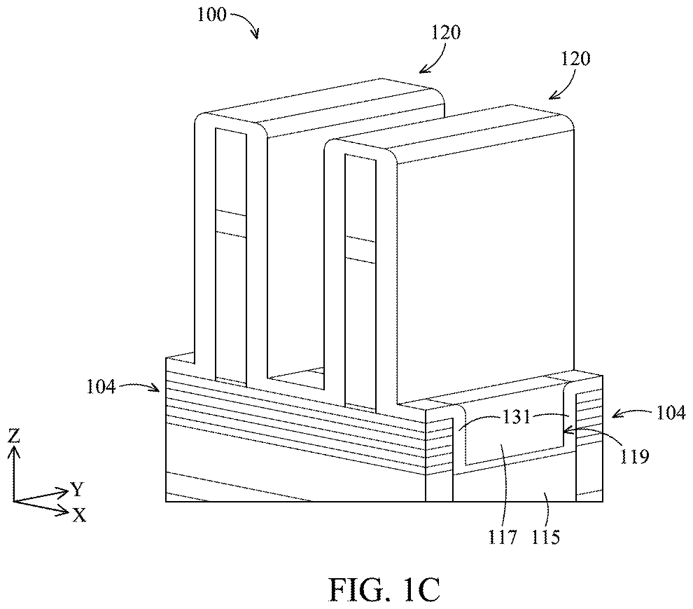

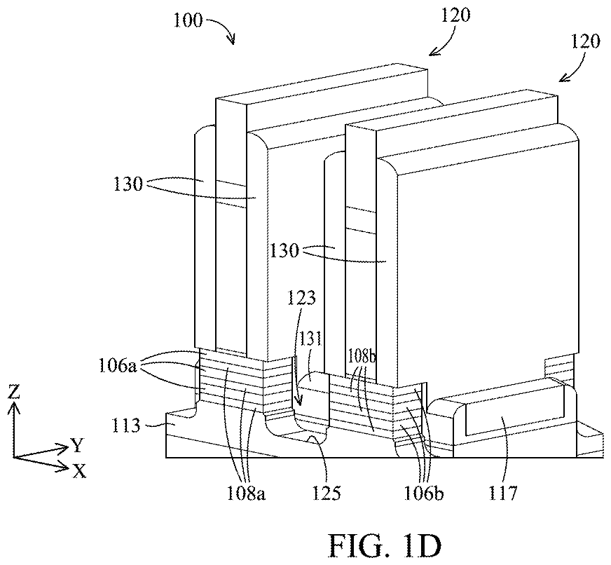

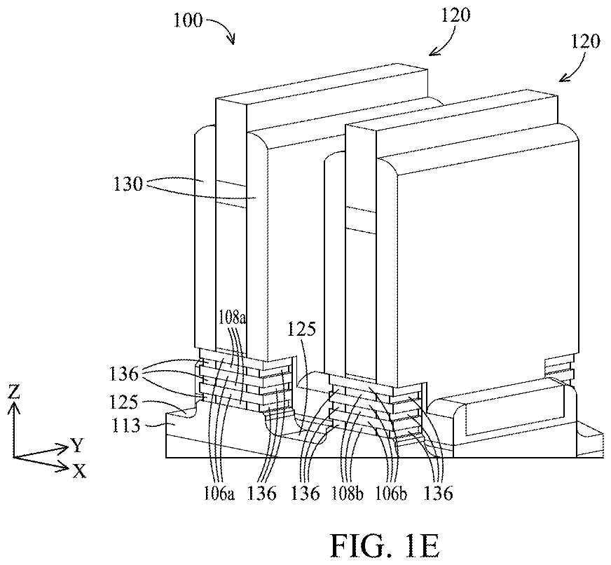

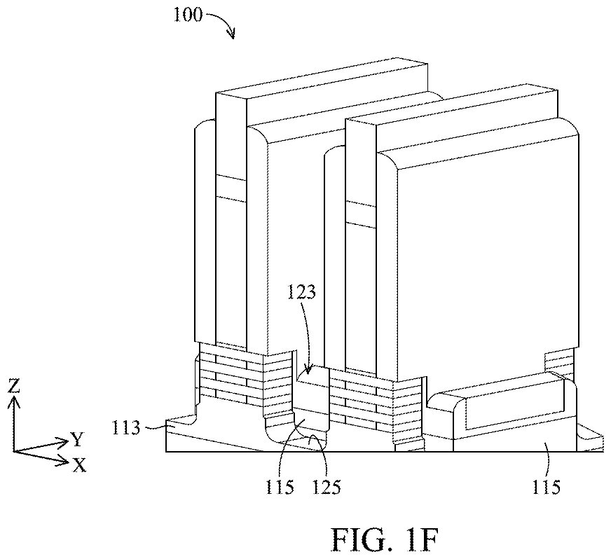

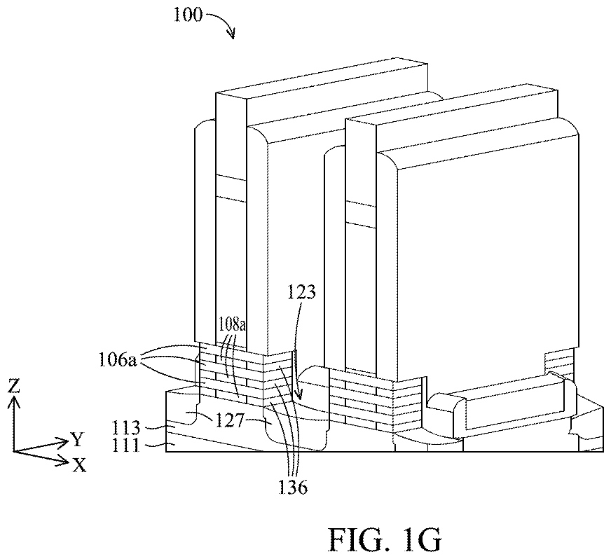

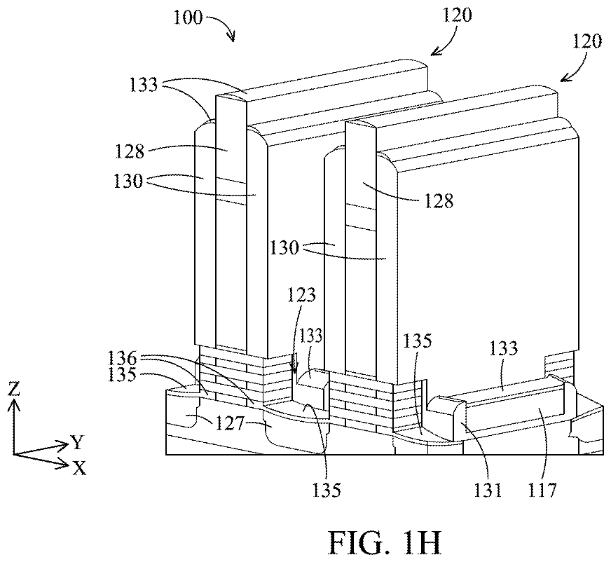

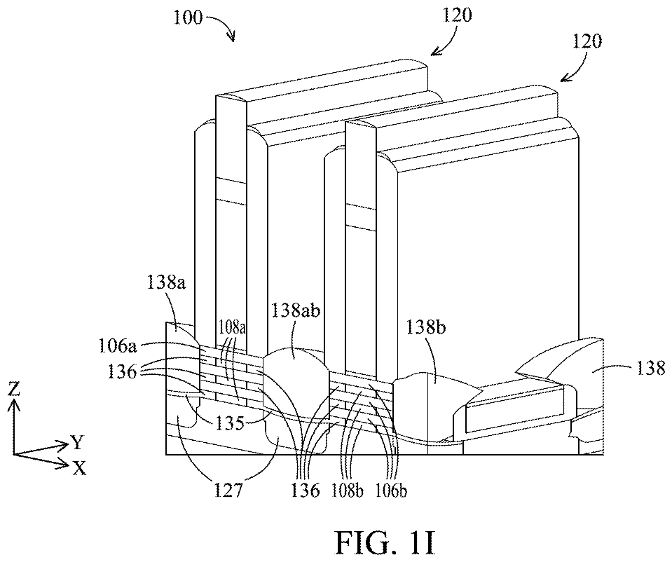

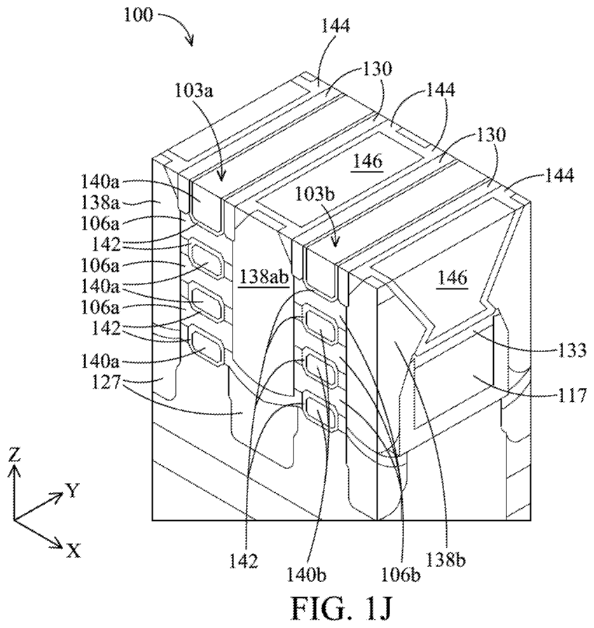

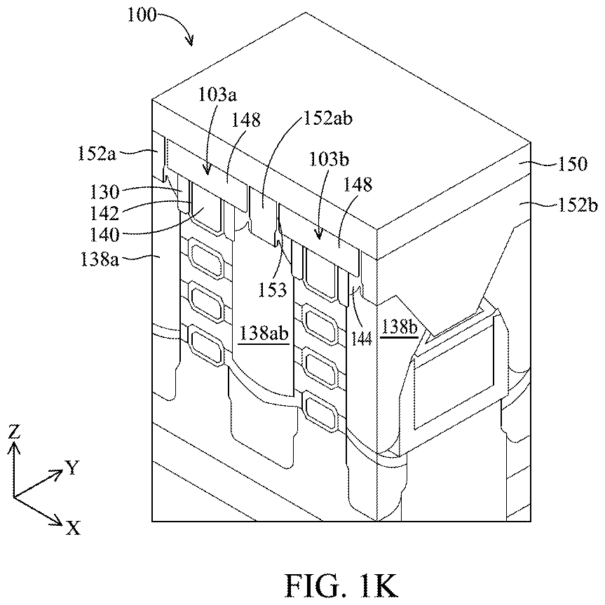

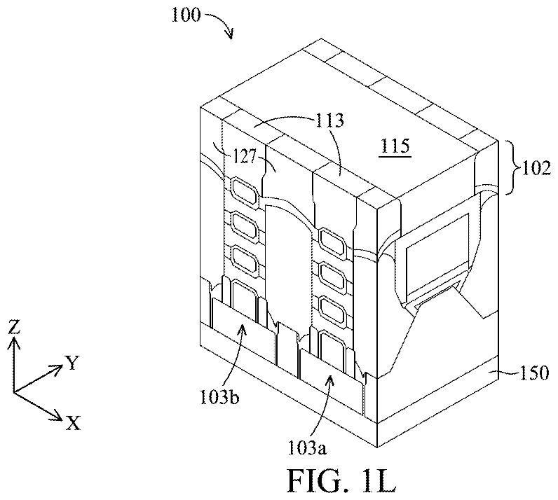

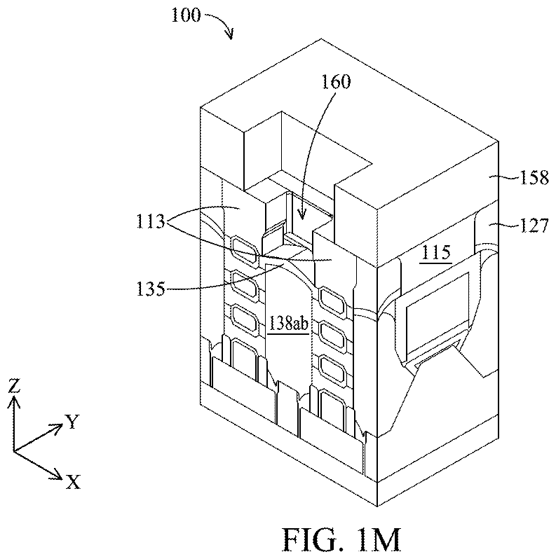

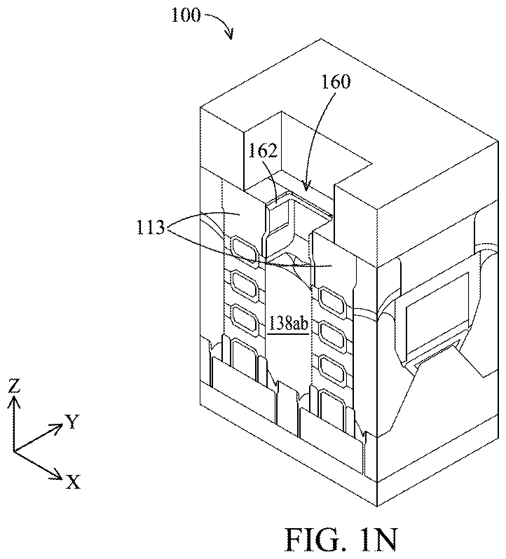

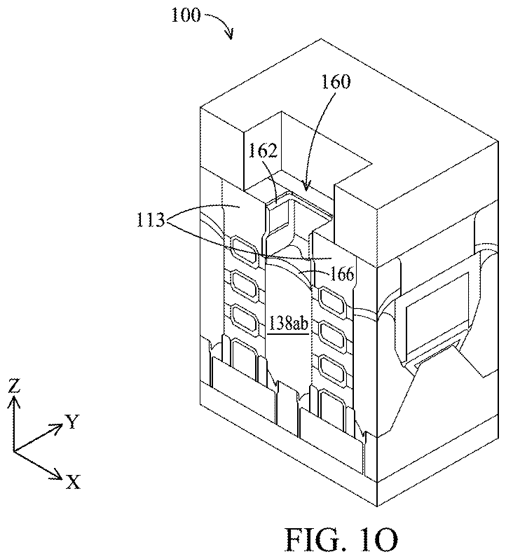

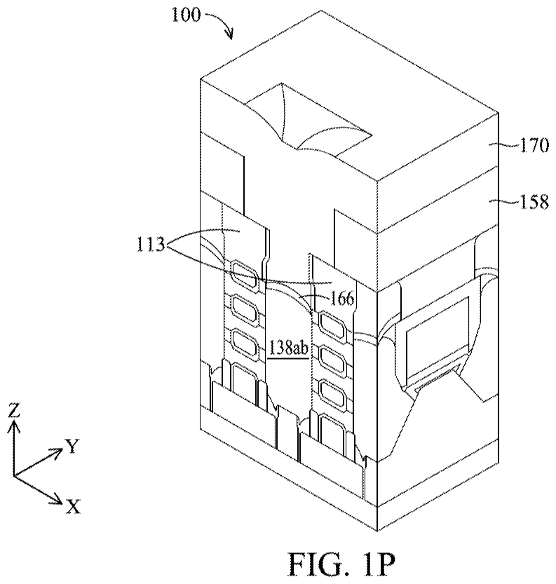

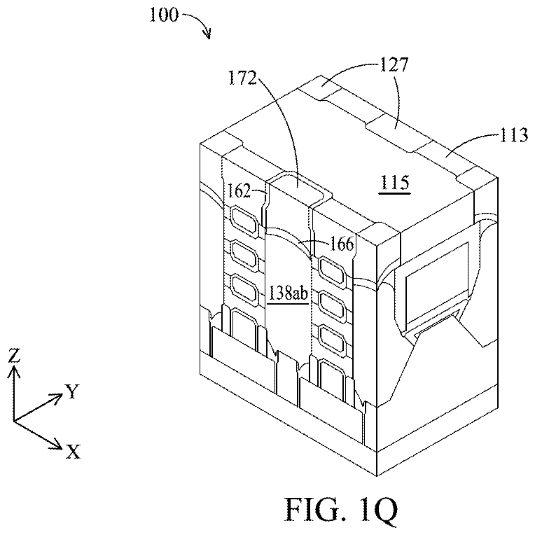

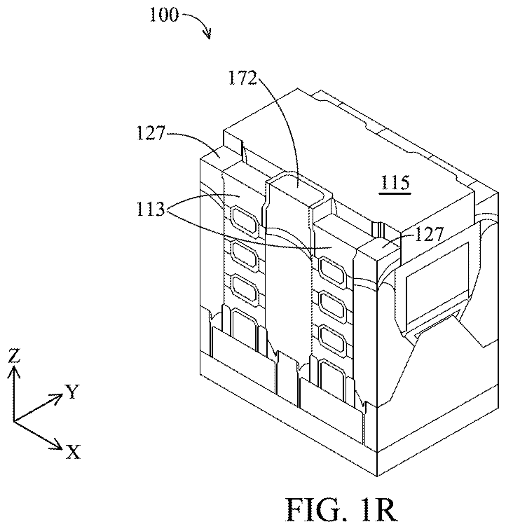

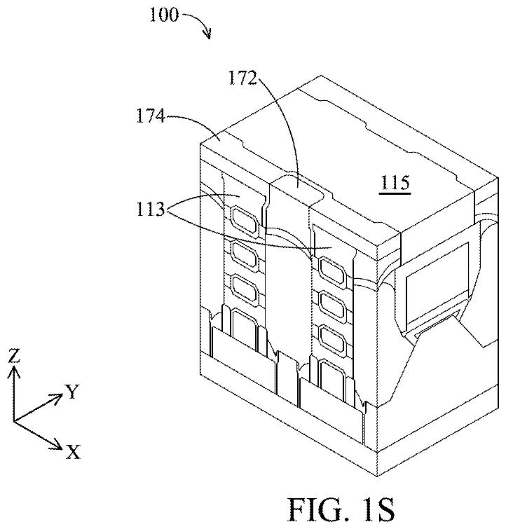

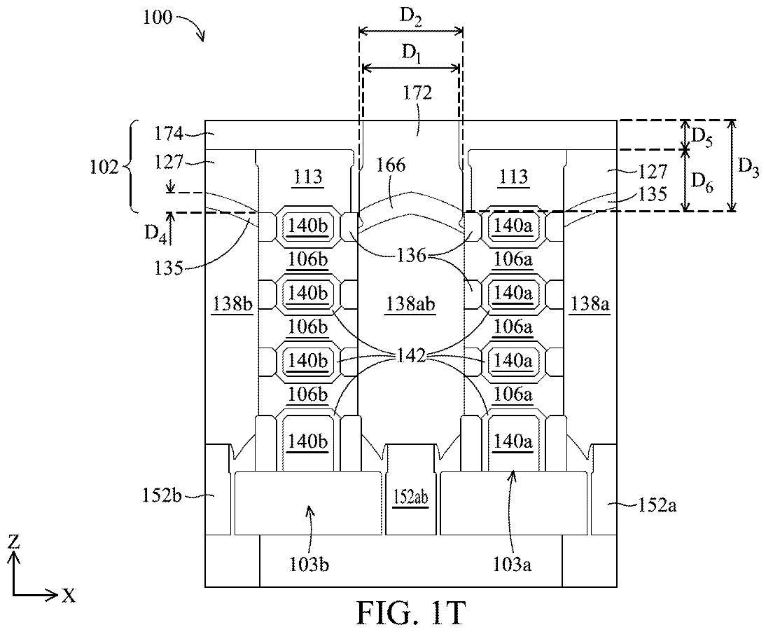

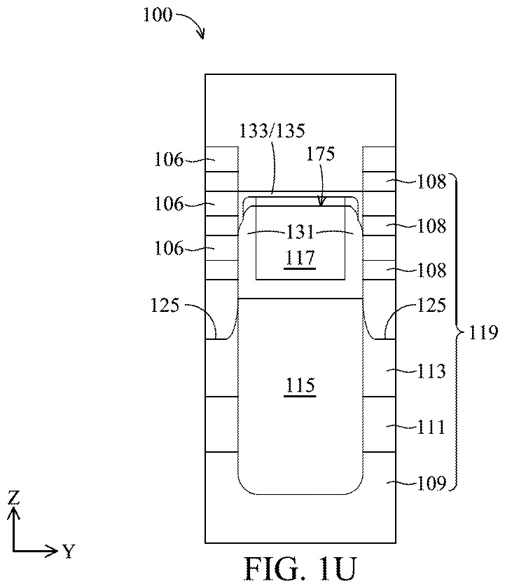

FIGS. 1A-1U are perspective and cross-sectional top and side views of a portion of an integrated circuit 100 fabricated according to some embodiments of the present disclosure. The fabrication process results in a plurality of semiconductor nanostructure transistors 103, as will be described in further detail below.

FIG. 1A is a perspective view of the integrated circuit 100 at an intermediate state of processing. The integrated circuit 100 includes a substrate 102. The substrate 102 may be a semiconductor substrate, such as a bulk semiconductor, or the like, which may be doped (e.g., with a p-type or an n-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

In FIG. 1A, the substrate 102 includes a layer 109, a layer 111 on the layer 109, and a layer 113 on the layer 111. In some embodiments, the layers 109 and 113 include silicon, while the layer 111 include silicon germanium. In particular, the layer 111 includes a semiconductor material that is selectively etchable with respect to the materials of the layers 109 and 113. The layers 109, 111, and 113 can include other semiconductor materials without departing from the scope of the present disclosure. In some embodiments, the layers 109, 111, and 113 can include a dielectric material.

The integrated circuit 100 includes semiconductor fins 104. Each fin includes a semiconductor stack including a plurality of semiconductor layers 105 and sacrificial semiconductor layers 107 alternating with each other. As will be set forth in further detail below, the semiconductor layers 105 will be patterned to form semiconductor nanostructures of a plurality of transistors. As set forth in more detail below, the sacrificial semiconductor layers 107 will eventually be entirely removed and are utilized to enable forming gate metals and other structures around the semiconductor nanostructures.

In some embodiments, the semiconductor layers 105 may be formed of a first semiconductor material suitable for n-type semiconductor nanostructure transistors, such as silicon, silicon carbide, or the like, and the sacrificial semiconductor layers 107 may be formed of a second semiconductor material suitable for p-type semiconductor nanostructure transistors, such as silicon germanium or the like. Each of the layers of the fins 104 may be epitaxially grown using a process such as chemical vapor deposition (CVD), atomic layer deposition (ALD), vapor phase epitaxy (VPE), molecular beam epitaxy (MBE), or the like.

Three layers of each of the semiconductor layers 105 and the sacrificial semiconductor layers 107 are illustrated. In some embodiments, the fins 104 may include one or two each or four or more each of the semiconductor layers 105 and the sacrificial semiconductor layers 107. Although the fins 104 are illustrated as including a sacrificial semiconductor layer 107 as the bottommost layer of the fins 104, in some embodiments, the bottommost layer of the fins 104 may be a semiconductor layer 105.

Due to high etch selectivity between the materials of the semiconductor layers 105 and the sacrificial semiconductor layers 107, the sacrificial semiconductor layers 107 of the second semiconductor material may be removed without significantly removing the material of the semiconductor layers 105, thereby allowing the semiconductor layers 105 to be released to form channel regions of semiconductor nanostructure transistors, as will be set forth in more detail below.

Prior to formation of the fins 104, the semiconductor layers 105 and the sacrificial semiconductor layers 107 are formed as a single stack without separate fins. In order to form the fins 104, an etching process has been performed in conjunction with a photolithography mask. The etching process can include an anisotropic etching process that etches in the downward direction. The etching process defines fins 104 by forming trenches through the sacrificial semiconductor layers 107, the semiconductor layers 105, and the substrate 102.

The fins 104 extend in the X direction and are separated from each other in the Y direction. The distance in the Y direction between adjacent fins 104 may be between 20 nm and 60 nm. Other distances may be utilized without departing from the scope of the present disclosure.

The fins 104 and the channels 106 may be patterned by any suitable method. For example, one or more photolithography processes, including double-patterning or multi-patterning processes, may be used to form the fins 104 and the channels 106. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. Each of the fins 104 and its overlying channels 106 may be collectively referred to as a “fin stack.”

FIG. 1A illustrates the fins 104 having vertically straight sidewalls. In some embodiments, the sidewalls are substantially vertical (non-tapered). In some embodiments, the fins 104 have tapered sidewalls, such that a width of each of the fins 104 increases in a direction towards the substrate 102.

In FIG. 1A, trench isolation regions 115, which may be shallow trench isolation (STI) regions, are formed between adjacent fins 104. The trench isolation regions 115 may be termed first trench isolation subregions or lower trench isolation subregions, as second or upper trench isolation subregions will be formed subsequently, as will be described in more detail below. The trench isolation regions 115 may be formed by depositing a dielectric material. In some embodiments, the dielectric material is formed over the substrate 102, the fins 104, and channels 106, and between adjacent fins 104. The dielectric material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 102, the fins 104, and the channels 106. Thereafter, the dielectric material may be formed over the liner of a material such as those discussed above.

An etching process has also been performed to recess the shallow trench isolation regions 115 to the level shown in FIG. 1A. The etching process can include a wet etch, dry etch, a timed etch, or other types of etching processes that can recess the height of the shallow trench isolation regions 115. The result is that the tops of the fins 104 are exposed. In particular, the semiconductor layers 105 and the sacrificial semiconductor layers 107 of each fin 104 are exposed.

Though not shown in FIG. 1A, appropriate wells (not separately illustrated) may also be formed in the fins 104, the semiconductor layers 105, and/or the trench isolation regions 115. Using masks, an n-type impurity implant may be performed in p-type regions of the substrate 102, and a p-type impurity implant may be performed in n-type regions of the substrate 102. Example n-type impurities may include phosphorus, arsenic, antimony, or the like. Example p-type impurities may include boron, boron fluoride, indium, or the like. An annealing may be performed after the implants to repair implant damage and to activate the p-type and/or n-type impurities. In some embodiments, in situ doping during epitaxial growth of the fins 104 and the semiconductor layers 105 may obviate separate implantations, although in situ and implantation doping may be used together.

In FIG. 1A, sacrificial gate structures 120 have been formed over the fins 104 and the trench isolation regions 115. Two sacrificial gate structures 120 are shown in FIG. 1A. In practice, many further sacrificial gate structures 120 may be formed substantially parallel to and concurrently with the sacrificial gate structures 120 shown in FIG. 1A. The sacrificial gate structures 120 extend in the Y direction, substantially perpendicular to the fins 104.

The fins 120 include a sacrificial gate dielectric layer 122. The gate dielectric layer 122 can include a SiO or other suitable dielectric materials. In some embodiments, the gate dielectric layer 120 has a low K dielectric material. The gate dielectric 120 can be deposited by CVD, ALD, or PVD.

The sacrificial gate structures include a sacrificial gate layer 124 on the sacrificial gate dielectric layer 122. The sacrificial gate layer can include materials that have a high etch selectivity with respect to the trench isolation regions 115. The sacrificial gate layer 124 may be a conductive, semiconductive, or non-conductive material and may be or include amorphous silicon, polycrystalline-silicon (polysilicon), poly-crystalline silicon-germanium (poly-SiGe), metallic nitrides, metallic silicides, metallic oxides, and metals. The sacrificial gate layer 124 may be deposited by physical vapor deposition (PVD), CVD, sputter deposition, or other techniques for depositing the selected material.

The sacrificial gate structures 120 include a dielectric layer 126 on the sacrificial gate layer 124 and a dielectric layer 128 of the dielectric layer 126. The dielectric layers 126 and 128 may correspond to first and second mask layers. The dielectric layer 126 can include silicon nitride, silicon oxynitride, or other suitable dielectric materials. The dielectric layer 126 can include silicon nitride, silicon oxynitride or other suitable dielectric materials. The dielectric layers 126 and 128 are different materials from each other and can be deposited using CVD, ALD, PVD, or other suitable deposition processes. Other materials and deposition processes can be utilized for the dielectric layers 126 and 128 without departing from the scope of the present disclosure.

After deposition of the layers 122, 124, 126, and 128, the dielectric layers 126 and 128 may be patterned to act as a mask layers. An etching process may then be performed in the presence of the patterned dielectric layers 126 and 128 in order to etch exposed regions of the sacrificial gate layer 124 and the sacrificial gate dielectric layer 122. This results in the structure of the sacrificial gate structures 120 shown in FIG. 1A.

In FIG. 1B, following formation of the sacrificial gate structures 120, one or more gate spacer layers 130 have been formed covering the sacrificial gate structures 120, the fins 104, the trench isolation regions 115, and the isolation structures 122. The gate spacer layer 130 can be formed by PVD, CVD, ALD, or other suitable deposition processes. Upper trench isolation region sidewall structures 131 are positioned on sidewalls of the fins 104 and on the top surface of the trench isolation region 115. The sidewall structures 131 are formed of a same material and in a same deposition process as the gate spacer layers 130. The gate spacer layers 130 can include one or more of SiO, SiN, SiON, SiCN, SiOCN, SiOC, or other suitable dielectric materials.

In FIG. 1C, upper trench isolation regions 117 have been formed on the sidewall structures 131 between the fins 104. The upper trench isolation regions 117 may correspond to a second trench isolation subregion. Collectively, the lower trench isolation subregion 115, the sidewall structures 131, and the upper trench isolation subregion 117 correspond to a multipart trench isolation region 119. The material of the upper trench isolation subregion 117 may be the same as the material of the lower trench isolation region 115. In one example, the trench isolation subregions 115 and 117 each include silicon oxide, while the sidewall structure 131 includes a different dielectric material than the trench isolation subregions 115 and 117. In one example, the sidewall structures 131 include silicon nitride. After deposition of the material of the upper trench isolation subregion 117, an etching process may be performed to recess the material of the trench isolation subregion 117 to the position shown in FIG. 1C.

In FIG. 1D, a first source/drain etching process has been performed to form source/drain trenches 123 in the fins 104 and in the layer 113 of the substrate. The bottom surface 125 of the trenches 123 are in the layer 113. The etching process selectively etches the semiconductor materials of the fins 104 and the layer 113 with respect to the dielectric materials of the trench isolation subregions 115 and 117 and the sidewall structures 131. The etching processes can include reactive ion etching (RIE), neutral beam etching (NBE), atomic layer etching (ALE), or the like. The etching processes forms the source/drain trenches 123 through the fins 104 in the areas exposed by the gate spacer layers 130. In practice, a large number of trenches 123 may be formed through fins 104 between large numbers of sacrificial gate structures 120.

The formation of the source/drain trenches 123 in the fins 104 results in formation of groups of stacked channels 106 from the semiconductor layers 105. Sacrificial semiconductor nanostructures 108 are formed from the sacrificial semiconductor layers 107. The result is that a large number of stacks channels 106 are formed from each fin 104. Each stack of channels 106 corresponds to the stacked channels 106 of a separate transistor, as will be described in more detail below.

FIG. 1D illustrates stacked channels 106a of a first transistor and stacked channels 106b of a second transistor. In practice, a large number of groups of stacked channels are formed from the fins 104 by forming a large number of source/drain trenches 123.

Structures associated with a first transistor may be given a suffix “a”, while structures associated with a second transistor may be given a suffix “b”. For example, the stacked channels 106a are stacked channels of the first transistor while the stacked channels 106b are stacked channels of the second transistor. The suffixes “a” and “b” may be omitted in this description when structures of a particular transistor are not referred to. For example, when a description applies to both the channels 106a and 106b, the description may simply refer to channels 106 without the suffixes “a” or “b”.

In FIG. 1E, inner spacers 136 have been formed. Prior to formation of the inner spacers 136, a selective etching process is performed to recess exposed end portions of the sacrificial semiconductor nanostructures 108 without substantially etching the channels 106. Next, the inner spacers 136 are formed by depositing a dielectric material to fill the recesses between the channels 106 formed by the previous selective etching process. The inner spacer 136 may be a suitable dielectric material, such as silicon carbon nitride (SiCN), silicon oxycarbonitride (SiOCN), or the like, formed by a suitable deposition method such as physical vapor deposition (PVD), CVD, ALD, or the like.

Initially, the deposition process may deposit a layer of dielectric material on the sidewalls of the gate spacers 130, on sidewalls of the channels 106, and on the bottom surface 125 of the source/drain trenches 123. An etching process, such as an anisotropic etching process, is then performed to remove portions of the inner spacer 136 disposed outside the recesses in the sacrificial semiconductor nanostructures 108. The remaining portions of the dielectric layer corresponds to the inner spacers 136 shown in FIG. 1E.

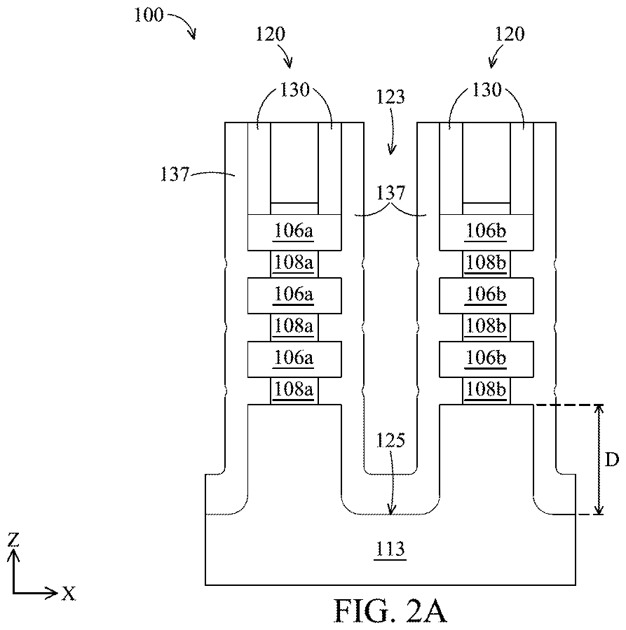

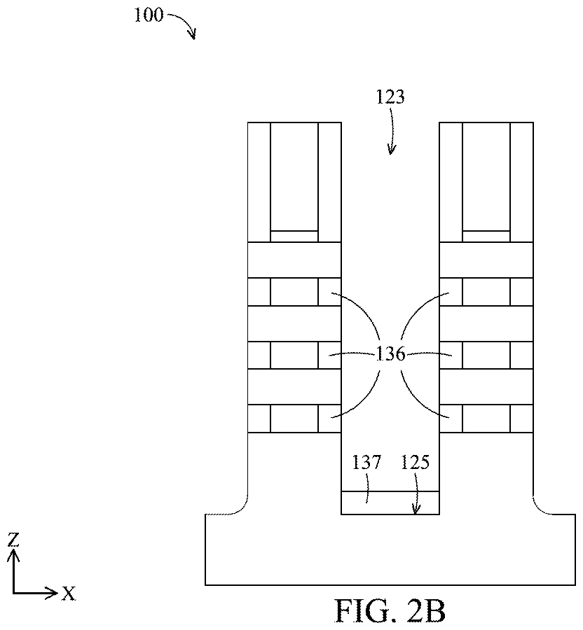

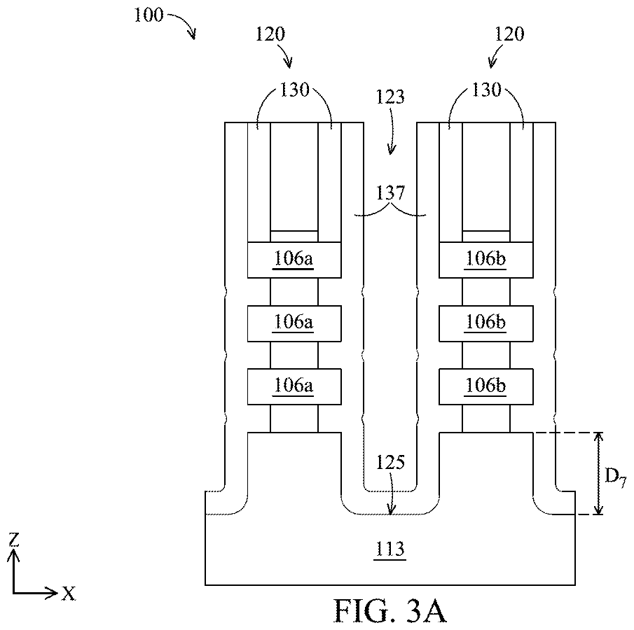

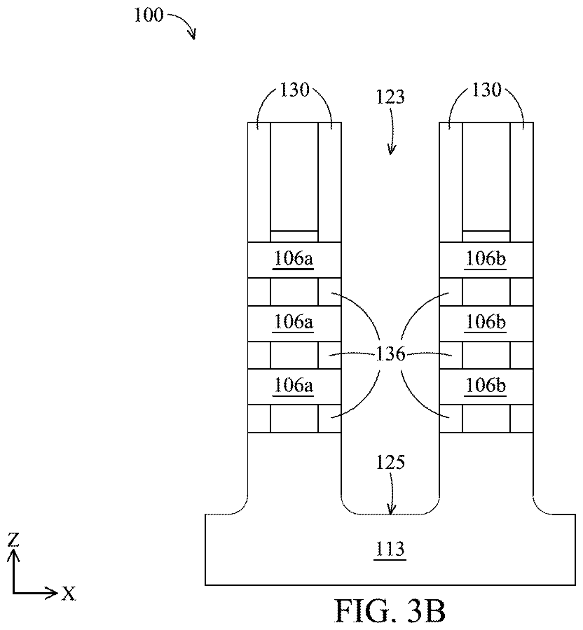

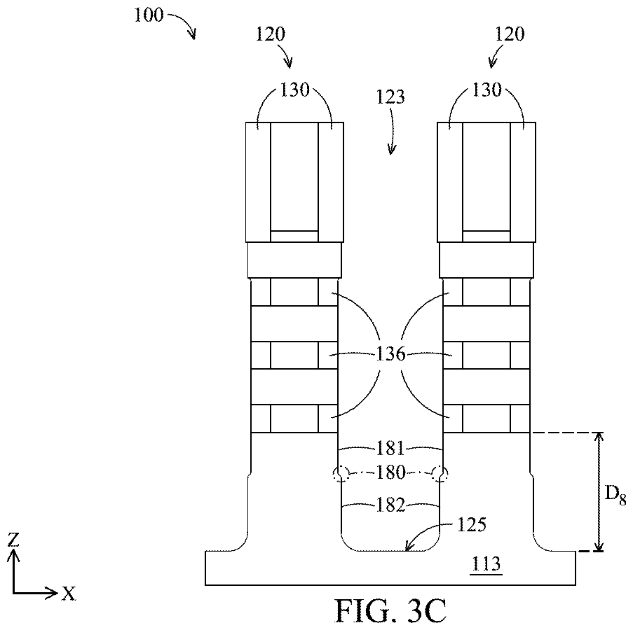

In FIG. 1F, a second source/drain etching process has been performed to deepen the source/drain trenches 123 after formation of the inner spacers 136. Accordingly, the bottom surface 125 of the source/drain trenches 123 is lowered, or moved deeper within the layer 113 of the substrate 102. The benefits of the multiple source/drain trench etching processes separated from each other by formation of the inner spacers 136 will be described in relation to FIGS. 2A-3C. In short, if the source/drain trenches 123 are formed to the depths shown in FIG. 1F prior to formation of the inner spacers 136, then the formation of the inner spacers 136 may result in some of the dielectric material of the layer used to form the inner spacers 136 remaining on the bottom surface 125 of the trenches 123.

In FIG. 1G, bottom semiconductor structures 127 have been formed in the bottoms of the source/drain trenches 123. The bottom semiconductor structures 127 or undoped (intrinsic) semiconductor structures. The bottom semiconductor structures 127 include a different semiconductor material than the semiconductor material of the substrate layer 113. In one example, the layer 113 include silicon, while the bottom semiconductor structures 127 include SiGe or SiGeB. The germanium concentration can be between 10% and 50%. The bottom semiconductor structures 127 are selectively etchable with respect to the layer 113. The bottom semiconductor structures 127 may be formed by an epitaxial growth from the layer 113. Alternatively, the bottom semiconductor structures 127 may be formed in another suitable manner.

The top surface of the bottom semiconductor structures 127 are below the bottom surface of the lowest stacked channels 106. In some embodiments, the top surface of the bottom semiconductor structures 127 may be substantially coplanar with a top surface of the layer 113 below the stacked channels 106.

In FIG. 1H, an etching process has been performed to remove an upper portion of the gate spacer layers 130 such that the gate spacer layers 130 do not cover the top surfaces of the layers 128. The etching process can include a timed anisotropic etching process that etches selectively in the downward direction.

In FIG. 1H, a layer of material has been deposited to form a dielectric layer 133 on the top surfaces of the layer 128, the sidewall spacers 130, the upper trench isolation subregions 117, and the spacers 131. The layer of dielectric material also forms bottom isolation layers 135 on the top surfaces of the bottom semiconductor structures 127 in the source/drain trenches 123. The bottom isolation layers 135 can include a material such as SiN, SiCN, SiOCN, SiOC, Si, Si: B, or other suitable dielectric materials or semiconductor materials. The bottom isolation layers 135 are selectively etchable with respect to the bottom semiconductor structures 127. The bottom isolation layers 135 can have a thickness between 3 nm and 8 nm, while the thickness of the inner spacers 136 may be between 3 nm and 15 nm. Other materials and thicknesses can be utilized for the bottom isolation layers 135 without departing from the scope of the present disclosure.

The bottom isolation layers 135 have a top surface that is lower than the bottom surface of the lowest stacked channels 106. The top surface of the bottom isolation layers 135 may be substantially coplanar with the top surface of the lowest inner spacers 136. The bottom isolation layers can help prevent leakage from the channels 106 to the substrate 102. The bottom isolation layer can act as a stop layer and can act as an isolation from the layers of the substrate 102.

In FIG. 1I source/drain regions 138 have been formed in the source/drain trenches 123. In the illustrated embodiment, the source/drain regions 138 are epitaxially grown from the channels 106. The source/drain regions 138 are grown on the bottom isolation regions 135 and contact the channels 106.

For each stack of channels 106, there are two source/drain regions 138. For the stack of channels 106a, there is a source/drain region 138a in direct contact with the channels 106a on the left side. There is a source/drain region 138ab in direct contact with the channels 106a on the right side and in direct contact with the left side of the channels 106b. There is a source/drain region 138a in direct contact with the right side of the channels 106b. Accordingly, the transistor associated with the channels 106a shares the source/drain region 138ab with the transistor associated with the channels 106b. Accordingly, the channels 106a extend in the X direction between source/drain regions 138a and 138ab. Likewise, the channels 106b extend in the X direction between the source/drain region 138ab and the source/drain region 138b.

The spacers 131 that remain on the trench isolation subregions 117 laterally confine the growth of source/drain regions 138 as they grow upward from the fins 104. In some embodiments, the source/drain regions 138 exert stress on the respective channels 106, thereby improving performance. The source/drain regions 138 are formed such that each sacrificial gate structure 120 is disposed between respective neighboring pairs of the source/drain regions 138. In some embodiments, the spacer layer 130 and the inner spacers 136 separate the source/drain regions 138 from the sacrificial gate layer 124 by an appropriate lateral distance (e.g., in the X-axis direction) to prevent electrical bridging to subsequently formed gates of the resulting device.

The source/drain regions 138 may include any acceptable material, such as appropriate for n-type or p-type devices. For n-type devices, the source/drain regions 138 include materials exerting a tensile strain in the channel regions, such as silicon, SiC, SiCP, SiP, or the like, in some embodiments. When p-type devices are formed, the source/drain regions 138 include materials exerting a compressive strain in the channel regions, such as SiGe, SiGeB, Ge, GeSn, or the like, in accordance with certain embodiments. The source/drain regions 138 may have surfaces raised from respective surfaces of the fins and may have facets. Neighboring source/drain regions 138 may merge in some embodiments to form a singular source/drain region 138 over two neighboring channel stacks. One example, an N-type source/drain region 138 can include SiAs or SiP with As or P dopant concentration between 5E19/cm\hat{ }3 and 5E21/cm\hat{ }3. In one example, a P type source/drain region 138 can include SiGe or SiGeB with a germanium concentration between 10% and 50% and a boron dopant concentration between 5E19/cm\hat{ }3 and 5E21/cm\hat{ }3.

The source/drain regions 138 may be implanted with dopants followed by an annealing process. The source/drain regions 138 may have an impurity concentration of between about 10¹⁹ cm⁻³ and about 10²¹ cm⁻³. N-type and/or p-type impurities for source/drain regions 138 may be any of the impurities previously discussed. In some embodiments, the source/drain regions 138 are in situ doped during growth.

In FIG. 1J, a contact etch stop layer (CESL) 144 and an interlayer dielectric (ILD) 146 have been formed. The CESL layer 144 can include a thin dielectric layer can formally deposited on exposed surfaces of the source/drain regions 138, the spacers 131, and the dielectric layer 133 over the trench isolation subregions 117. The CESL layer 144 can include SiN, SiC, SiOC, SiOCN, SiON, or other suitable dielectric materials. The CESL 144 can be deposited by CVD, ALD, PVD, or other suitable deposition processes.

The dielectric layer 146 covers the CESL 144. The dielectric layer 146 can include SiO, SiON, SiN, SiC, SiOC, SiOCN, SiON, or other suitable dielectric materials. The dielectric layer 146 can be deposited by CVD, ALD, PVD, or other suitable deposition processes.

In FIG. 1J, the sacrificial gate structures 120 have been removed from between the gate spacer layers 130. Removal of the sacrificial gate structures 120 includes removal of the dielectric layers 122, 124, 126, and 128 via one or more etching processes. Removal of the sacrificial gate structures 120 can include first performing a planarization process, such as a CMP to level the top surfaces of the sacrificial gate layer 124 and gate spacer layer 130. The planarization process may also remove the dielectric layers 126 and 128 on the sacrificial gate layer 124, and portions of the gate spacer layer 130 along sidewalls of the dielectric layers 126 and 128. Accordingly, the top surfaces of the sacrificial gate layer 124 are exposed.

Next, the sacrificial gate layer 124 can be removed in an etching process, so that recesses are formed. In some embodiments, the sacrificial gate layer 124 is removed by an anisotropic dry etch process. For example, the etching process may include a dry etch process using reaction gases that selectively etch the sacrificial gate layer 124 without etching the spacer layer 130. The sacrificial gate dielectric layer 122, when present, may be used as an etch stop layer when the sacrificial gate layer 124 is etched. The sacrificial gate dielectric layer 122 may then be removed after the removal of the sacrificial gate layer 124.

In FIG. 1J, channels 106 have been released by removal of the sacrificial semiconductor nanostructures 108. The sacrificial semiconductor nanostructures 108 can be removed by a selective etching process using an etchant that is selective to the material of the sacrificial semiconductor nanostructures 108, such that the sacrificial semiconductor nanostructures 108 are removed without substantially etching the channels 106. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like. In some embodiments, the sacrificial semiconductor nanostructures 108 are removed and the channels 106 are patterned to form channel regions of both PFETs and NFETs.

After removal of the sacrificial semiconductor nanostructures 108, a gate dielectric layer 142 has been deposited. The gate dielectric layer 142 can include an interfacial gate dielectric layer. The interfacial gate dielectric layer is deposited on all exposed surfaces of the channels 106. The interfacial gate dielectric layer surrounds the channels 106. The interfacial gate dielectric layer can include a dielectric material such as silicon oxide, silicon nitride, or other suitable dielectric materials. The interfacial gate dielectric layer can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer can be formed by a thermal oxidation process, a chemical vapor deposition (CVD) process, or an atomic layer deposition (ALD) process. The interfacial gate dielectric layer can have a thickness between 0.5 nm and 2 nm. Other materials, deposition processes, and thicknesses can be utilized for the interfacial gate dielectric layer without departing from the scope of the present disclosure.

The gate dielectric layer 142 also includes a high-K dielectric layer is deposited in a conformal deposition process. The conformal deposition process deposits the high-K dielectric layer on the interfacial gate dielectric layer and on sidewalls of the gate spacer layers 130. The high-K gate dielectric layer surrounds the channels 106. The high-K gate dielectric layer has a thickness between 1 nm and 3 nm. The high-K dielectric layer includes one or more layers of a dielectric material, such as HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K dielectric layer may be formed by CVD, ALD, or any suitable method. Other thicknesses, deposition processes, and materials can be utilized for the high-K dielectric layer without departing from the scope of the present disclosure.

In FIG. 1J, a gate metal 140 has been deposited. The gate metal 140 is deposited on all exposed surfaces of the high-K dielectric layer. The gate metal 140 substantially surrounds channels 106. Although the gate metal 140 is shown as a single layer in FIG. 1J, in practice, the gate metal 140 can include one or more conductive liner layers, work function layers, and gate fill layers that collectively make up the gate metal. The gate metal can include one or more of Ti, TiN, Ta, TaN, Al, Cu, Co, Ru, W, Au, or other suitable conductive materials. The gate metal 140 can be deposited by PVD, ALD, or CVD. Other configurations, materials, and deposition processes can be utilized for the gate metal 140 without departing from the scope of the present disclosure.

At the stage of processing shown in FIG. 1J, transistors 103a and 103b are substantially complete. The transistor 103a includes channels 106a extending between the source/drain regions 138a and 138ab and acting as stacked channels of the transistor 103a. The gate metal 140a acts as a gate electrode surrounding the channels 106a. The transistor 103b includes channels 106b extending between the source/drain regions 138ab and 138b and acting as stacked channels of the transistor 103b. The gate metal 140b acts as a gate electrode surrounding the channels 106b. In FIG. 1J, a CMP process has been performed to planarize the top surfaces of the gate metal 140, the gate dielectric 142, the gate spacers 130, the dielectric layers 144 and 146, and the source/drain regions 138.

In FIG. 1K, a hard mask layer 148 has been deposited on the top surfaces of the structures that were planarized by the CMP process described in relation to FIG. 1G. The hard mask layer 148 can include a dielectric material such as SiO, SiON, SiN, SiC, SiOC, SiOCN, SiON, or other suitable dielectric materials. The hard mask layer 148 and other lower layers have been patterned to expose portions of the source/drain regions 138. A liner layer 153 is then deposited on sidewalls of the hard mask layer 148. The liner layer 153 can include a dielectric material such as SiO, SiON, SiN, SiC, SiOC, SiOCN, SiON, or other suitable dielectric materials.

Source/drain contacts 152 are formed in the trenches formed in the hard mask layer 148 and in contact with top surfaces of the source/drain regions 138. The source/drain contacts 152 can include one or more of Ti, TiN, Ta, TaN, Al, Cu, Co, Ru, W, Au, or other suitable conductive materials. A source/drain contact 152a is in contact with the source/drain region 138a. A source/drain contact 152ab is in contact with the source/drain region 138ab. A source/drain contact 152b is in contact with the source/drain region 138b. Though not shown in FIG. 1K, in practice, a silicide layer may be formed on top of the source/drain regions 138 prior to formation of the source/drain contacts 152. A CMP process may be performed after formation of the source/drain contacts 152.

In FIG. 1K, a dielectric layer 150 has been formed on the planarized surfaces after formation of the source/drain contacts 152. The dielectric layer 150 can include a dielectric material such as SiO, SiON, SiN, SiC, SiOC, SiOCN, SiON, or other suitable dielectric materials. Metal interconnect structures may be formed in the dielectric layer 150 to provide electrical contact the source/drain contacts 152.

In FIG. 1L, the integrated circuit 100 has been flipped for backend processing. In particular, the substrate 102 is now positioned on top in the dielectric layer 150 is not positioned on a bottom. A CMP process has been performed to reduce the thickness of the substrate 102, including lower trench isolation subregion 115, the layer 113, and the bottom semiconductor structures 127. The CMP process entirely removes the layers 109 and 111.

In FIG. 1M, a dielectric layer 158 has been deposited on the substrate 102. The dielectric layer 150 can include a dielectric material such as SiO, SiON, SiN, SiC, SiOC, SiOCN, SiON, or other suitable dielectric materials. After deposition of the dielectric layer 158, a backside trench 160 has been formed in the dielectric layer 158 and through the bottom semiconductor structure 127. The backside trench 160 exposes the bottom isolation layer 135. Because the semiconductor material of the bottom semiconductor structure 127 is selectively etchable with respect to the materials of the semiconductor layer 113 and the lower trench isolation subregion 115, there can be relaxed alignment requirements when forming the opening in the layer 158. Accordingly, the backside trench 160 is self-aligned and will reliably land that the bottom isolation layer 135.

In FIG. 1N, the bottom isolation layer 135 has been removed from the source/drain region 138ab, fully exposing the source/drain region 138ab in the backside trench 160. A liner layer 162 has been deposited on sidewalls of the layer 113 of the substrate 102 and on other exposed structures. The liner layer can include a dielectric material such as SiO, SiON, SiN, SiC, SiOC, SiOCN, SiON, or other suitable dielectric materials. Formation of the liner layer 162 can include conformally depositing the material of the liner layer on all exposed surfaces and then performing an anisotropic etching process that etches in the vertical direction, thereby removing the liner layer 162 from the source/drain region 138ab and the top surfaces of the layer 113 and the trench isolation subregion 115.

In FIG. 1O, a silicide 166 has been formed on the exposed surface of the source/drain region 138ab. The silicide 166 can TiSi, CrSi, TaSi, MoSi, ZrSi, HfSi, ScSi, Ysi, HoSi, TbSI, GdSi, LuSi, DySi, ErSi, YbSi, or other types of silicide. The silicide 166 can have a thickness between 1 nm and 10 nm. The silicide 166 can help ensure proper electrical connection between the source/drain region 138ab and a subsequent backside conductive via. The silicide can be formed by depositing a metal in a performing an annealing process to cause the metal to react with the semiconductor material of the source/drain region 138ab in order to form the silicide 166.

In FIG. 1P, a metal layer 170 has been deposited in the backside trench 160 and on exposed surfaces of the dielectric layer 158. The metal layer 170 is in direct contact with the silicide 166. The metal layer 170 can include one or more of W, Ru, Co, Cu, Ti, TiN, Ta, TaN, Mo, Ni, or other suitable conductive materials.

In FIG. 1Q, a CMP process has been performed to entirely remove the layer 158. The CMP process also removes the metal layer 170 from back surfaces of the integrated circuit 100. A backside source/drain contact 172 or conductive via remains in contact with the silicide 166 and the backside trench 160.

In FIG. 1R, an etchback process has been performed to recess the layer 113 and the bottom semiconductor structures 127. The etching process can be selected to etch the semiconductor materials of the layer 113 and the backside semiconductor structures 127 selectively with respect to the exposed dielectric and metal materials of the backside of the wafer 100. The result is that the back surfaces of the layer 113 and the bottom semiconductor structures 127 are recessed with respect to the back surface of the trench isolation subregion 115 and the backside via 172.

In FIG. 1S, a dielectric layer 174 has been deposited on the backside of the integrated circuit 100. The dielectric layer 174 fills the recesses previously performed in the layer 113 and the backside semiconductor structures 127. The dielectric layer 174 can include a dielectric material such as SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or other suitable dielectric materials. A CMP process has been performed to planarize the backside of the integrated circuit 100.

FIG. 1T is a cross-sectional view of the integrated circuit 100 at the stage of processing shown in FIG. 1S, in accordance with one embodiment. FIG. 1T illustrates various dimensions associated with materials and structures of the integrated circuit 100. In some embodiments, the backside source/drain contact 172 has a width dimension D1 at the back surface and the X direction between 8 nm and 40 nm. In some embodiments, the backside source/drain contact 172 has a width dimension D2 at the silicide interface in the X direction between 10 nm and 50 nm. in some embodiments, the backside source/drain contact 172 has a thickness dimension D3 in the Z direction between 5 nm and 70 nm.

In some embodiments, the silicide 166 has a thickness in the Z direction between 1 nm and 10 nm. In some embodiments, the backside semiconductor structure 127 has a curved surface such that a vertical distance D4 between a center portion of the curved surface and an edge portion is between 1 nm and 5 nm due to a smile effect or a dishing effect during growth of the bottom semiconductor structures 127. In some embodiments, the bottom semiconductor structures 127 have a total thickness dimension D6 in the Z direction between 2 nm and 30 nm. In some embodiments, the backside dielectric layer 174 has a thickness dimension D5 in the Z direction between 5 nm and 40 nm. In some embodiments, the bottom isolation layers 135 have a thickness between 2 nm and 5 nm. The bottom isolation layers 135 and the source/drain regions 138 have curved surfaces based on the curvature of the bottom semiconductor regions 127.

In some embodiments, the liner layer 162 is not present. In these cases, the backside source/drain contact 172 is in direct contact with the layer 113 and the layer 174.

In some embodiments, the bottom isolation layer 135 is not formed. In these cases, there is no physical separation between the bottom semiconductor structures 127 and the source/drain regions 138, where backside source/drain contacts are not formed.

The process described in relation to FIGS. 1A-IT can result in various features including the bottom semiconductor structures 127, the first and second trench isolation subregions 115 and 117, the spacer layer 131 and the trench isolation subregion 117 between stacks of channels 106 in the Y direction, the backside dielectric cap layer 174, and the backside source/drain contact 172 (backside conductive via). Furthermore, the process described in relation to FIGS. 1A-1T provides a backside conductive via 172 with a small pitch. The backside source/drain contact 172 can have a small critical dimension without leakage between the backside source/drain contact 172 and the gate metal 140. The backside conductive via 172 can have a low resistance.

FIG. 1U is an enlarged cross-sectional view of a portion of the integrated circuit 100, in accordance with some embodiments. FIG. 1U illustrates how the bottom isolation layer 133/135 is positioned on top of the upper trench isolation subregion 117. This, combined with the multiple stacked subregions 115 and 117 of the trench isolation region 119 result in less loss in the trench isolation region height between adjacent stacks of channels 106 than would otherwise occur. Furthermore, the trench isolation subregion 117 has a substantially planar top surface rather than a U-shaped top surface that can occur when material is lost during a precleaning process prior to forming source/drain regions 138.

FIG. 2A is a cross-sectional view of an integrated circuit 100, in accordance with some embodiments. FIG. 2A corresponds to an example process for forming inner spacers 136, in accordance with some embodiments. In the example FIG. 2A, a single deep source/drain trench etch is performed rather than the multiple source/drain trench etches described in relation to FIGS. 1D and 1E. A dielectric material 137 has been deposited on sidewalls of the gate spacers 130, on sidewalls of the stacked channels 106, in the recesses of the stacked semiconductor nanostructures 108, and on the bottom surface 125 of the trench 123. Due to the depth and narrowness of the trench 123 during deposition of the dielectric material 137 is possible that the dielectric material 137 will thicker in the bottom of the trench 123 and on sidewalls of the trench 123.

In FIG. 2B, an etching process has been performed to remove the dielectric layer 137 from sidewalls of the trench 123, thereby forming the defined inner spacers 136. However, due to the increased thickness of the dielectric material 125 of the bottom surface 125 of the trench 123, some of the dielectric layer 137 remains at the bottom of the trench 123. This can prevent formation of the bottom semiconductor structures 127.

FIGS. 3A-3C are cross-sectional views of the integrated circuit 100, in accordance with some embodiments. FIGS. 3A-3C illustrate the multiple source/drain trench etching steps described in relation to FIGS. 1D-1E, in accordance with some embodiments. In FIG. 3A, the source/drain trench 123 has been etched with a first etching process resulting in a bottom surface 125 that is less deep than shown in FIG. 2A. The dielectric layer 137 is then deposited as described in relation to FIG. 2A. However, because the trench 123 is not as deep in FIG. 3A as in FIG. 2A, the thickness of the dielectric layer 137 of the bottom of the trench 123 is substantially the same as the thickness on the sidewalls of the trench 123. The trench 123 has a depth dimension D7 in the layer 113 after the first etching process. The dimension D7 may be between 5 nm and 20 nm.

In FIG. 3B, the dielectric layer 137 has been etched to remove the dielectric layer 137 from the sidewalls of the trench 123 and the bottom surface 125 of the trench 123. This defines the inner spacers 136. The dielectric layer 137 has been entirely removed from the bottom surface 125 of the trench 123.

In FIG. 3C, a second source/drain etching process has been performed, as described in relation to FIG. 1E. The second source/drain etching process increases the depth of the source/drain trench 123 in the layer 113. The bottom surface 125 is lower in FIG. 3C than in FIG. 3B. The trench 123 has a depth dimension D8 in the layer 113 after the first etching process. The dimension D8 may be between 10 nm and 30 nm.

Furthermore, the multiple source/drain trench etching processes can leave notches or steps 180 in the sidewalls of the layer 113 in the trench 123. The sidewalls of the trench 123 and the layer 113 include a first substantially vertical portion 181, a step 180, and a second vertical portion 182 before rounding at the bottom. Accordingly, the portion of the trench 123 in the layer 113 will be wider at an upper region than in a lower region.

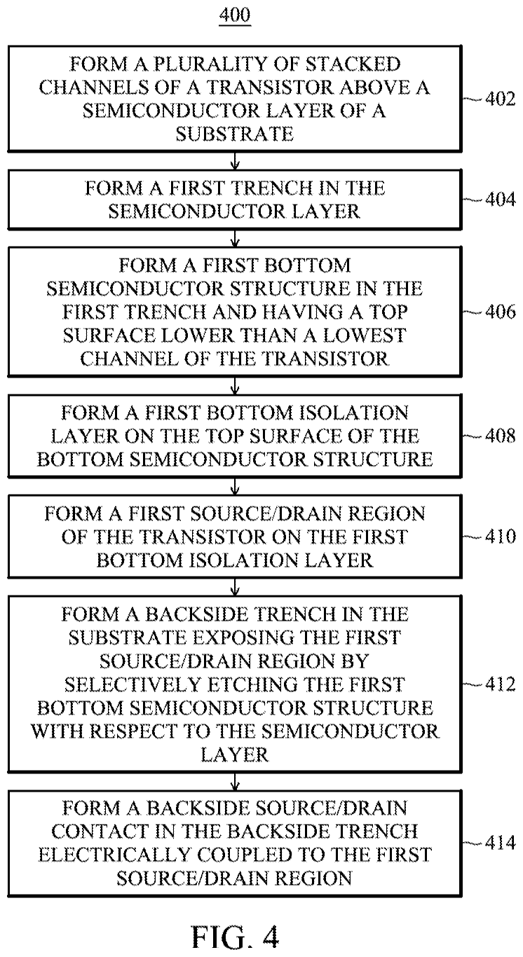

FIG. 4 is a flow diagram of a method 400 for forming an integrated circuit, in accordance with some embodiments. The method 400 can utilize the structures, processes, and systems described in relation to FIGS. 1A-3C. At 402, the method 400 includes forming a plurality of stacked channels of a transistor above a semiconductor layer of a substrate. One example of stacked channels are the stacked channels 106a of FIG. 1T. One example of a transistor is the transistor 103a of FIG. 1T. One example of a semiconductor layer is the layer 113 of FIG. 1T. One example of a substrate is the substrate 102 of FIG. 1T. At 404, the method 400 includes forming a first trench in the semiconductor layer. One example of a first trench is the trench 123 of FIG. 1D. At 406, the method 400 includes forming a first bottom semiconductor structure in the first trench and having a top surface lower than a lowest channel of the transistor. One example of a first bottom semiconductor structure is the bottom semiconductor structure 127 of FIG. 1G. At 408, the method 400 includes forming a first bottom isolation layer on the top surface of the bottom semiconductor structure. One example of a bottom isolation layer is the bottom isolation layer 135 of FIG. 1H. At 410, the method 400 includes forming a first source/drain region of the transistor on the first bottom isolation layer. One example of a first source/drain region is the source/drain region 138ab of FIG. 1I. At 412, the method 400 includes forming a backside trench in the substrate exposing the first source/drain region by selectively etching the first bottom semiconductor structure with respect to the semiconductor layer. One example of a backside trench is the backside trench 160 of FIG. 1M. At 414, the method 400 includes forming a backside source/drain contact in the backside trench electrically coupled to the first source/drain region. One example of a backside source/drain contact is the backside source/drain contact 172 of FIG. 1Q.

Embodiments of the disclosure provide transistors having a plurality of stacked channels above a semiconductor layer of a substrate. Embodiments of the present disclosure provide bottom semiconductor structures below source/drain regions of the transistors and separated from the source/drain regions by bottom isolation layers. The bottom semiconductor structures are selectively etchable with respect to the semiconductor layer. Backside source/drain contacts can be formed in contact with selected source/drain regions by selectively removing the bottom semiconductor structure and bottom isolation region at the selected source/drain regions. The result is that backside source/drain contacts can be formed with very small pitches and small critical dimensions (CD). This reduces leakage currents between the backside source/drain contacts and the gate metals of the transistors. Better functioning integrated circuits are produced and wafer yields are increased.

In one embodiment, a device includes a substrate including a semiconductor layer and a transistor on the substrate. The transistor includes a first source/drain region, a second source/drain region, and a plurality of stacked channels over the semiconductor layer each extending between the first source/drain region and the second source/drain region. The device includes a bottom isolation layer below and in contact with the first source/drain region and a bottom semiconductor structure below and in contact with the bottom isolation layer and in contact with a sidewall of the semiconductor layer. The bottom semiconductor structure has a different semiconductor material than the semiconductor layer.

In one embodiment, a method includes forming a plurality of stacked channels of a transistor above a semiconductor layer of a substrate, forming a first trench in the semiconductor layer, forming a first bottom semiconductor structure in the first trench and having a top surface lower than a lowest channel of the transistor, and forming a first bottom isolation layer on the top surface of the bottom semiconductor structure. The method includes forming a first source/drain region of the transistor on the first bottom isolation layer, forming a backside trench in the substrate exposing the first source/drain region by selectively etching the first bottom semiconductor structure with respect to the semiconductor layer, and forming a backside source/drain contact in the backside trench electrically coupled to the first source/drain region.

In one embodiment, a device includes a substrate including a semiconductor layer and a transistor. The transistor includes stacked channels above the semiconductor layer and a first source/drain region in contact with the channels. The device includes a backside source/drain contact in the substrate directly below and electrically coupled to the first source/drain region. A sidewall of the source/drain contact has step in contact with a step in a sidewall of the semiconductor layer. The device includes a frontside source/drain contact directly above and electrically coupled to the first source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate including a semiconductor layer;
a transistor on the substrate and including:
a first source/drain region;
a second source/drain region; and
a plurality of stacked channels over the semiconductor layer each extending between the first source/drain region and the second source/drain region;
a bottom isolation layer below and in contact with the first source/drain region; and
a bottom semiconductor structure below and in contact with the bottom isolation layer and in contact with a sidewall of the semiconductor layer, the bottom semiconductor structure having a different semiconductor material than the semiconductor layer.

2. The device of claim 1, comprising a backside source/drain contact in the substrate directly below and electrically coupled to the second source/drain region.

3. The device of claim 2, comprising a frontside source/drain contact directly above and electrically coupled to the second source/drain region.

4. The device of claim 1, wherein the sidewall of the semiconductor layer has a step that is in contact with the bottom semiconductor structure.

5. The device of claim 1, comprising a trench isolation region including:
a lower trench isolation subregion in contact with the bottom semiconductor structure and the semiconductor layer; and
an upper trench isolation subregion above the lower trench isolation subregion and separated from the lower trench isolation subregion by a dielectric layer of a same material as the bottom isolation layer.

6. The device of claim 5, comprising a dielectric spacer layer positioned between the upper trench isolation subregion and the first source/drain region.

7. The device of claim 5, wherein the substrate includes a dielectric layer in direct contact with the semiconductor layer, the bottom semiconductor structure, and the lower trench isolation subregion.

8. The device of claim 1, wherein the semiconductor layer is silicon and the bottom semiconductor structure is silicon germanium.

9. The device of claim 1, wherein bottom semiconductor structure has a concave top surface, wherein the bottom isolation layer has a convex bottom surface in contact with the concave top surface of the bottom semiconductor structure.

10. The device of claim 9, wherein the first source/drain region has a convex bottom surface in contact with the bottom isolation layer.

11. A method, comprising:
forming a plurality of stacked channels of a transistor above a semiconductor layer of a substrate;
forming a first trench in the semiconductor layer;
forming a first bottom semiconductor structure in the first trench and having a top surface lower than a lowest channel of the transistor;
forming a first bottom isolation layer on the top surface of the bottom semiconductor structure;
forming a first source/drain region of the transistor on the first bottom isolation layer;
forming a backside trench in the substrate exposing the first source/drain region by selectively etching the first bottom semiconductor structure with respect to the semiconductor layer; and
forming a backside source/drain contact in the backside trench electrically coupled to the first source/drain region.

12. The method of claim 11, comprising forming a frontside source/drain contact above and electrically coupled to the first source/drain region.

13. The method of claim 11, comprising forming inner spacers between the stacked channels, wherein forming the first trench includes:
etching the semiconductor layer with a first etching process before forming the inner spacers; and
deepening the first trench by etching the semiconductor layer with a second etching process after forming the inner spacers.

14. The method of claim 13, wherein a sidewall of the first trench has a step after the second etching process.

15. The method of claim 11, comprising:
forming a second trench in the semiconductor layer;
forming a second bottom semiconductor structure in the second trench and having a top surface lower than the lowest channel of the first transistor;
forming a second bottom isolation layer on the top surface of the bottom semiconductor structure; and
forming a second source/drain region of the transistor on the second bottom isolation layer.

16. The method of claim 11, comprising:
forming a lower trench isolation subregion of a trench isolation region;
forming a dielectric layer of a same material as the first bottom isolation layer on the lower trench isolation subregion; and
forming an upper trench isolation subregion of the trench isolation region directly above the lower trench isolation subregion and separated from the lower trench isolation subregion by the dielectric layer.

17. The method of claim 16, comprising forming a silicide between the first source/drain region and the backside source/drain contact.

18. A device, comprising:
a substrate including a semiconductor layer;
a transistor including:
stacked channels above the semiconductor layer;
a first source/drain region in contact with the channels;
a backside source/drain contact in the substrate directly below and electrically coupled to the first source/drain region, wherein a sidewall of the source/drain contact has step in contact with a step in a sidewall of the semiconductor layer; and
a frontside source/drain contact directly above and electrically coupled to the first source/drain region.

19. The device of claim 18, wherein the transistor includes a second source/drain region in contact with the channels, the device comprising:
a bottom isolation layer below and in contact with the second source/drain region; and
a bottom semiconductor structure below and in contact with the bottom isolation layer and in contact with the semiconductor layer, the bottom semiconductor structure having a different semiconductor material than the semiconductor layer.

20. The device of claim 19, comprising a trench isolation region including:
a lower trench isolation subregion in contact with the bottom semiconductor structure and the semiconductor layer; and
an upper trench isolation subregion above the lower trench isolation subregion and separated from the lower trench isolation subregion by a dielectric layer of a same material as the bottom isolation layer.
